(19) United States
(12) Patent Application Publication
(10) Pub. No.: US 2023/0347387 A1
(43) Pub. Date: Nov. 2, 2023

(54) WAFER CLEANING WATER SUPPLY DEVICE

(71) Applicant: KURITA WATER INDUSTRIES LTD., Tokyo (JP)

(72) Inventor: Nobuko GAN, Tokyo (JP)

(73) Assignee: KURITA WATER INDUSTRIES LTD., Tokyo (JP)

(21) Appl. No.: 18/006,933

(22) PCT Filed: Mar. 18, 2021
(86) PCT No.: PCT/JP2021/011274

§ 371 Date: Jan. 26, 2023

(30) Foreign Application Priority Data
Jul. 30, 2020 (JP) 2020-129743

(51) Int. Cl. B08B 3/08; B08B 3/14; B08B 13/00

(52) U.S. Cl. CPC B08B 3/08; B08B 3/14; B08B 13/00; B08B 2203/002

(57) ABSTRACT

Wafer cleaning water supply device (1) has a wafer cleaning water production unit (2) that prepares wafer cleaning water (W1) from ultrapure water (W) supplied from a supply path (5), a reservoir (3) for the prepared wafer cleaning water, and a wafer cleaning water supply pipe (6) that supplies the wafer cleaning water (W1) stored in the reservoir (3) to a cleaning nozzle (4A) of a cleaning machine (4). A return pipe (7) is connected to the wafer cleaning water supply pipe (6) on the cleaning machine (4) side so as to be branched at a distance (t) from the tip of the cleaning nozzle (4A), and the wafer cleaning water (W1) which is excessive in the cleaning machine (4) can be returned to the reservoir (3). Such a wafer cleaning water supply device can reduce excessive wafer cleaning water.

### TECHNICAL FIELD

The present invention relates to a wafer cleaning water supply device capable of stably supplying cleaning water that contains very low concentrations of solutes such as alkali, acid, oxidant, and reductant and that is effective in a step of cleaning/rinsing wafers for semiconductors, etc.

### BACKGROUND ART

The step of cleaning silicon wafers for semiconductors, etc. may include using water in which solutes effective for controlling the pH and the redox potential are dissolved in ultrapure water at very low concentrations (such water will be referred to as wafer cleaning water). This wafer cleaning water uses ultrapure water as the basic material, to which a minimum amount of acid/alkali and/or oxidant/reductant is added in order to allow the wafer cleaning water to have liquid properties such as the pH and the redox potential that match the purpose of each step such as a cleaning step or a rinsing step. In this operation, H₂ gas dissolution is used to give the reducing properties, but for adjusting the pH and giving the oxidizing properties, a method of adding a small amount of liquid chemical agents (chemical feeding) is generally used in such a manner that the chemical solution is injected with a pump or in a pressurization scheme with inert gas.

In this case, if the flow volume of ultrapure water is constant, the chemical feeding is easy to obtain a desired solute concentration, but in a cleaning machine in which the wafer cleaning water is actually used, the supply/stop of the cleaning water poured onto the wafer is controlled by opening and closing a plurality of valves, and the flow volume fluctuates irregularly. In response to this fluctuation, dissolution control is performed by various schemes such as proportional control for the ultrapure water flow volume and PID control with a received signal from a concentration monitor so that the solute concentration of the wafer cleaning water falls within a desired range. Particularly in a single-wafer type cleaning machine having a plurality of cleaning chambers, however, the chemical feeding control that can sufficiently follow the irregular flow volume fluctuation cannot be realized, and as a result, the liquid quality of the cleaning water/rinsing water poured onto the wafer remains under control in a wide range far from the ideal value.

### SUMMARY OF THE INVENTION

### Problems to be Solved by the Invention

In this context, there is a simple method of giving priority to stabilizing the liquid quality and continuing to produce and supply the wafer cleaning water under a certain condition, but in this case, excess water is discharged without any modification. In recent multi-chamber single-wafer cleaning machines, the difference between the maximum flow volume required instantaneously and the minimum flow volume is large, and if a volume of dilute functional water (wafer cleaning water) equal to or larger than the maximum flow volume is continuously supplied, a considerable amount of excessive wafer cleaning water (excess water) will be discharged, thus leading to a problem in an aspect of a burden on the supply and drainage facilities or excessive use/discharge of the chemical solution.

To solve this problem of excess water, a wafer cleaning water production device of a circulation type is used, which is configured to return the excess water through a pipe to a reservoir provided between the wafer cleaning water production device and the cleaning machine, rather than draining the excess water.

However, the return pipe used in the case of returning the excess water to the reservoir is branched and connected immediately before entering the cleaning machine, and when the wafer cleaning water is not used, the cleaning water remains in a wafer cleaning water supply pipe in the cleaning machine; therefore, even if it remains for a short period of time, the cleanness of the cleaning water deteriorates and the liquid quality of the cleaning water such as the pH changes, thus adversely affecting the wafer cleaning effect. For this reason, immediately before processing the wafer with the wafer cleaning water, an operation called pre-dispensing is required on the cleaning machine side such that the cleaning water remaining in a region from the wafer cleaning water inlet of the cleaning machine to the nozzle tip is ejected to be discharged and is replaced with cleaning water of high cleanliness and predetermined liquid quality. The pre-dispensing is carried out for each cleaning step, and the discharged cleaning water is sent to the supply and drainage facilities, but the return pipe is connected immediately before entering the cleaning machine, and therefore the amount of discharged cleaning water becomes large, leading to problems in that the burden on the supply and drainage facilities is large and the chemical solution is excessively used. It has thus been desired to minimize the amount of wafer cleaning water (excess water) discharged during the pre-dispensing.

The present invention has been made in view of the above problems, and an object of the present invention is to provide a wafer cleaning water supply device capable of reducing excessive wafer cleaning water.

### Means for Solving the Problems

To achieve the above-described object, the present invention provides a wafer cleaning water supply device comprising: a wafer cleaning water production unit that dissolve a predetermined amount of a chemical agent in a flow volume of ultrapure water thereby to produce wafer cleaning water having a predetermined concentration of the chemical agent; a reservoir that stores the produced wafer cleaning water; a wafer cleaning water supply pipe that supplies the wafer cleaning water to a cleaning machine; and a return pipe that branches from the wafer cleaning water supply pipe and returns excessive wafer cleaning water from the cleaning machine to the reservoir, wherein the return pipe that returns the excessive wafer cleaning water to the reservoir branches at a point of 10 m or less from a wafer cleaning water ejection portion of the cleaning machine (Invention 1).

According to the invention (Invention 1), a predetermined amount of the chemical solution is added to ultrapure water to produce the wafer cleaning water having a predetermined concentration, which is temporarily stored in the reservoir and supplied from this reservoir to the cleaning machine. In a conventional wafer cleaning water supply device, the pipe for sending the cleaning water into the cleaning machine and the pipe for returning the cleaning water to the reservoir are branched just before the entrance of the cleaning machine; therefore, when the cleaning water is not used, a considerable amount of the cleaning water remains inside the cleaning machine, and every time the cleaning machine is operated/stopped, the cleaning water remaining on the cleaning machine side is discharged, so that the excess water cannot be completely recovered. Accordingly, in order to recover the cleaning water discharged during the pre-dispensing as much as possible and reuse it as cleaning water, a structure is adopted in which the return pipe is branched at a point of 10 m or less from the wafer cleaning water ejection portion for the wafer cleaning water. This can significantly reduce the amount of cleaning water discharged during the pre-dispensing. Moreover, the time required to supply the cleaning water with stable water quality can be significantly shortened.

In the above invention (Invention 1), the return pipe may be preferably provided on the cleaning machine side, and the wafer cleaning water can be preferably circulated through the reservoir, the wafer cleaning water supply pipe, and the return pipe (Invention 2).

According to the invention (Invention 2), the cleaning water can be constantly supplied into the cleaning machine, and when the cleaning water is not used, the excess water can be returned to the reservoir from the return pipe. This can minimize the amount of cleaning water retained in the wafer cleaning water supply pipe in the cleaning machine and the deterioration of the cleaning water quality due to the retention even when the wafer cleaning water is not used. Furthermore, the pre-dispensing may be unnecessary or its amount can be minimized, and it is expected to reduce the burden on the supply and drainage facilities and improve the excessive use/discharge of the chemical solution.

In the above invention (Invention 1, 2), the chemical agent may be preferably a liquid, and a mechanism for adding the chemical agent to the ultrapure water may be preferably a liquid supply pump or a pressure-feeding means comprising: a closed tank filled with the chemical agent; and a pressurizing means that supplies inert gas to the closed tank (Invention 3).

According to the invention (Invention 3), it is easy to control the addition of a very small amount of the chemical solution to the flow volume of the ultrapure water, and the wafer cleaning water having a predetermined concentration can be stably supplied to the reservoir.

In the above invention (Invention 1 to 3), the reservoir may be preferably provided with a detection means that detects a water level, and the wafer cleaning water supply device may preferably include a control means that controls start/stop of production of the wafer cleaning water in the wafer cleaning water production unit based on liquid level information obtained by the detection means (Invention 4). In the above invention (Invention 1 to 3), a production amount of the wafer cleaning water in the wafer cleaning water production unit can be preferably adjusted in multiple stages, and the wafer cleaning water supply device may preferably include a control means that controls, in multiple stages, the production amount of the wafer cleaning water in the wafer cleaning water production unit in accordance with a water level of the reservoir (Invention 5).

According to the invention (Invention 4, 5), the wafer cleaning water can be produced efficiently by controlling the production of the wafer cleaning water in accordance with the water level of the reservoir.

In the above invention (Invention 1 to 5), a discharge mechanism may be preferably provided between the wafer cleaning water production unit and the reservoir (Invention 6).

According to the invention (Invention 6), the wafer cleaning water can be discharged out of the system until the wafer cleaning water stabilizes at a predetermined concentration.

In the above invention (Invention 6), the discharge mechanism may be preferably connected to a return pipe that communicates with a supply source for the ultrapure water, and the discharge mechanism may be preferably provided with an ion exchange device and/or a catalyst device capable of removing a chemical agent component in the wafer cleaning water (Invention 7).

According to the invention (Invention 7), by removing the chemical agent component from the wafer cleaning water to be discharged, the wafer cleaning water can be returned to the supply source for the ultrapure water and reused.

In the above invention (Invention 1 to 7), the production unit may preferably have a mechanism for removing dissolved oxygen from the ultrapure water or the wafer cleaning water (Invention 8).

According to the invention (Invention 8), the fluctuation in the pH and/or redox potential of the produced wafer cleaning water can be suppressed.

### Advantageous Effect of the Invention

According to the wafer cleaning water supply device of the present invention, the return pipe that returns the excessive wafer cleaning water to the reservoir is branched at a point of 10 m or less from the wafer cleaning water ejection portion of the cleaning machine; therefore, even when the pre-dispensing is carried out in a general cleaning machine, the amount of excess water discharged can be significantly reduced, and the time required to supply the cleaning water with stable water quality can also be shortened.

### BRIEF DESCRIPTION OF DRAWINGS

FIG. 1 is a schematic diagram illustrating a wafer cleaning water supply device according to a first embodiment of the present invention.

FIG. 2 is a schematic diagram illustrating the configuration of the wafer cleaning water supply device on the cleaning machine side according to the first embodiment.

FIG. 3 is a schematic diagram illustrating a wafer cleaning water production unit in the first embodiment.

FIG. 4 is a schematic diagram illustrating another example of the wafer cleaning water supply device according to the first embodiment.

FIG. 5 is a schematic diagram illustrating a wafer cleaning water supply device according to a second embodiment of the present invention.

FIG. 6 is a schematic diagram illustrating the configuration of the wafer cleaning water supply device on the cleaning machine side according to the second embodiment.

FIG. 7 is a schematic diagram illustrating another example of the wafer cleaning water supply device according to the second embodiment.

FIG. 8 is a schematic diagram illustrating a second aspect of the wafer cleaning water production unit of the wafer cleaning water supply device according to the present invention.

FIG. 9 is a schematic diagram illustrating a third aspect of the wafer cleaning water production unit of the wafer cleaning water supply device according to the present invention.

FIG. 10 is a schematic diagram illustrating a fourth aspect of the wafer cleaning water production unit of the wafer cleaning water supply device according to the present invention.

FIG. 11 is a schematic diagram illustrating a fifth aspect of the wafer cleaning water production unit of the wafer cleaning water supply device according to the present invention.

FIG. 12 is a schematic diagram illustrating a sixth aspect of the wafer cleaning water production unit of the wafer cleaning water supply device according to the present invention.

FIG. 13 is a schematic diagram illustrating a seventh aspect of the wafer cleaning water production unit of the wafer cleaning water supply device according to the present invention.

FIG. 14 is a schematic diagram illustrating an eighth aspect of the wafer cleaning water production unit of the wafer cleaning water supply device according to the present invention.

FIG. 15 is a graph illustrating the number of fine particles on a wafer in Example 1 and Comparative Examples 1 and 2.

FIG. 16 is a graph illustrating the pH of cleaning water in Example 1 and Comparative Examples 1 and 2.

FIG. 17 is a graph illustrating a dissolved oxygen concentration (DO) of cleaning water in Example 1 and Comparative Examples 1 and 2.

### EMBODIMENTS FOR CARRYING OUT THE INVENTION

### First Embodiment

### <Wafer Cleaning Water Supply Device>

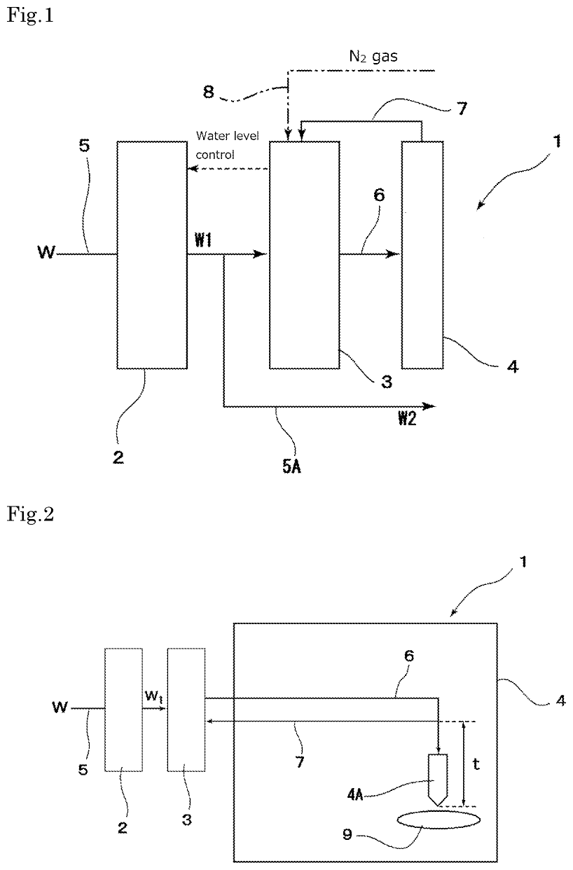

FIGS. 1 to 3 illustrate a wafer cleaning water supply device according to a first embodiment of the present invention. In FIGS. 1 and 2, a wafer cleaning water supply device 1 has a wafer cleaning water production unit 2 that prepares wafer cleaning water W1 from ultrapure water W supplied from a supply path 5, a reservoir 3 for the prepared wafer cleaning water W1, and a wafer cleaning water supply pipe 6 that supplies the wafer cleaning water W1 stored in the reservoir 3 to a cleaning nozzle 4A of a cleaning machine 4. A return pipe 7 is connected to the wafer cleaning water supply pipe 6 on the cleaning machine 4 side so as to be branched at a distance (t) from the tip of the cleaning nozzle 4A, and the wafer cleaning water W1 which is excessive in the cleaning machine 4 can be returned to the reservoir 3. In the present embodiment, the return pipe 7 may be branched at a point at which a distance (t) from the tip of the cleaning nozzle 4A is within 10 m, preferably 8 m, and particularly 6 m. Reference character 5A represents a discharge path for drain water.

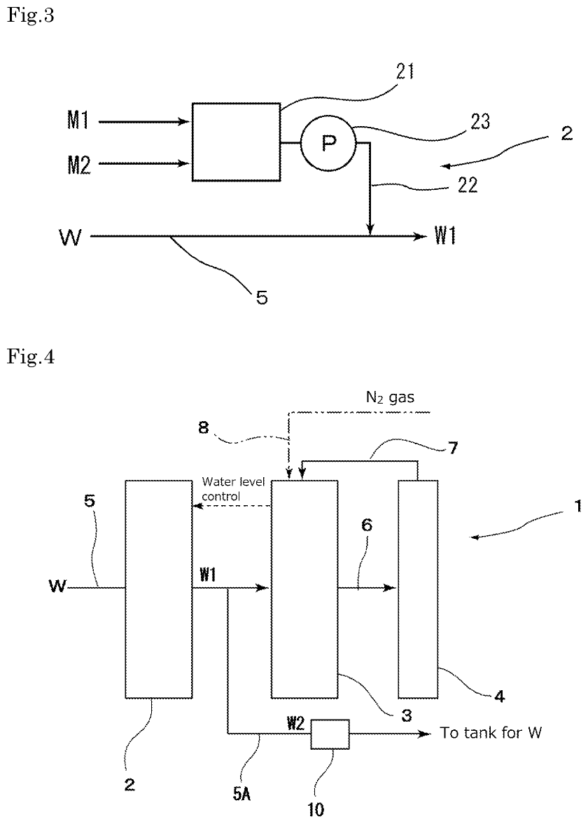

For use in the wafer cleaning water supply device 1 as described above, the wafer cleaning water production unit 2 may be composed of, for example, as illustrated in FIG. 3, a chemical solution tank 21 that stores predetermined amounts of a first chemical solution M1 and a second chemical solution M2 having respective predetermined concentrations, a chemical solution supply pipe 22 that communicates from the chemical solution tank 21 to the supply path 5 for the ultrapure water W, and a pump 23 that sends and supplies the chemical solutions.

The reservoir 3 for use may be made of a high-purity material that does not impair the purity of the wafer cleaning water W1, and its elution from the inner wall is at a negligible level. To prevent the increase in the dissolved oxygen, the reservoir 3 may be connected to a supply pipe 8 for an inert gas such as N₂ gas so that the gas phase side is always filled with the inert gas at a constant pressure.

The supply path 5 for the ultrapure water W, the wafer cleaning water supply pipe 6, and the chemical solution supply pipe 22 may each be provided with a flow volume measuring means such as a flow meter (not illustrated), and the wafer cleaning water supply pipe 6 and the reservoir 3 or chemical solution supply pipe 22 may each be provided with a pH meter, a redox potential meter, etc. (not illustrated).

### <Method of Supplying Wafer Cleaning Water>

The description will then be directed to a method of supplying the wafer cleaning water W1 using the wafer cleaning water supply device 1 as described above.

### (Wafer Cleaning Water Preparation Step)

First, the ultrapure water W is distributed to the supply path 5 from a supply source (not illustrated) of the ultrapure water W, and a predetermined amount of the ultrapure water W is supplied to the wafer cleaning water production unit 2. On the other hand, since the first chemical solution M1 and the second chemical solution M2 are stored in the chemical solution tank 21, the pump 23 is controlled by a control device based on the supply amount of the ultrapure water W (flow volume in the supply path 5) so that the first chemical solution M1 and the second chemical solution have predetermined concentrations with respect to the ultrapure water W, and the first chemical solution M1 and the second chemical solution M2 are supplied from the chemical solution supply pipe 22 to prepare the wafer cleaning water W1.

In the present specification, preferred properties of the ultrapure water W as the raw water may be, for example, resistivity: 18.1 MΩ·cm or more, fine particles: 1000 particles/L or less with a particle diameter of 50 nm or more, viable bacteria: 1 bacterium/L or less, TOC (Total Organic Carbon): 1 μg/L or less, total silicon: 0.1 μg/L or less, metals: 1 ng/L or less, ions: 10 ng/L or less, hydrogen peroxide; 30 μg/L or less, and water temperature: 25±2° C.

One of the first chemical solution M1 and the second chemical solution M2 may be preferably, for example, a pH adjuster. The pH adjuster is not particularly limited, but when adjusting the pH to lower than 7, an acidic solution such as hydrochloric acid, nitric acid, sulfuric acid, or acetic acid can be used. When adjusting the pH to 7 or higher, an alkaline solution such as ammonia, sodium hydroxide, potassium hydroxide, or TMAH can be used.

The other of the second chemical solution M2 and the first chemical solution M1 may be preferably a redox potential adjuster. When adjusting the redox potential to a high level, hydrogen peroxide solution or the like can be used as the redox potential adjuster. When adjusting the redox potential to a low level, a solution of oxalic acid, hydrogen sulfide, potassium iodide, or the like can be used.

Both the first chemical solution M1 and the second chemical solution M2 may be added, or either one may otherwise be added. Thus, the desired wafer cleaning water W1 can be prepared by controlling the additive amount of either or both of the first chemical solution M1 and the second chemical solution M2 from the chemical solution tank 21 based on the flow volume of the ultrapure water W so that the predetermined concentrations are obtained.

Immediately after the production of the wafer cleaning water W1 is started (i.e., in the initial stage), the concentration of the first chemical solution M1 and/or the second chemical solution M2 in the wafer cleaning water W1 may not fall within a predetermined range. To deal with this, the solute concentration of the wafer cleaning water W1 to be supplied to the reservoir 3 can be maintained with a high degree of accuracy through preliminarily determining the time and processing amount required for the concentration to stabilize at a desired level and discharging the wafer cleaning water W1 as drain water W2 from the discharge path 5A until reaching the determined time and processing amount. The amount discharged in this operation becomes drainage, but it is a small amount with respect to the total amount of water.

### (Storage Step)

The wafer cleaning water W1 thus prepared is supplied to the reservoir 3 without any modification. In this operation, N₂ gas having a constant pressure is supplied to the reservoir 3 from an N₂ gas supply pipe 31 to fill the upper space of the reservoir 3 with the N₂ gas. This can prevent the dissolved oxygen in the wafer cleaning water W1 from increasing in the reservoir 3, thereby suppressing the fluctuations of the pH and the redox potential due to the increase in the dissolved gas.

In the present embodiment, by providing the reservoir with a water level measuring means such as a level sensor or a weight measuring device (not illustrated), the wafer cleaning water production unit 2 can be controlled to turn on/off based on the output from the water level measuring means so that when the amount of water held in the reservoir 3 falls below a certain level, the wafer cleaning water production unit 2 starts the production of the wafer cleaning water W1. This allows the wafer cleaning water W1 to be produced efficiently. Moreover, even when the water level of the reservoir 3 is a certain level or higher and the wafer cleaning water production unit 2 is in a stopped state, the wafer cleaning water production unit 2 may continue to pass the ultrapure water at a very small flow volume, and the purity in the wafer cleaning water production unit 2 can thereby be kept high. The outlet water which has passed through in this operation may be either discharged or merged to the ultrapure water return pipe.

The present invention is not limited to the above method, and it is also possible to preliminarily determine multiple stages (e.g., two stages of a high flow rate condition and a low flow rate condition) of the flow volume conditions capable of producing the wafer cleaning water W1 having a desired concentration with a high degree of accuracy and switch the production from the high flow rate to the low flow rate when the water level of the reservoir rises and reaches a certain level of a high water level while switching the production from the low flow rate to the high flow rate when the water level falls and reaches a certain level of a low water level. In this case, there is no need for drainage during the period required for concentration stabilization at the start of production, and a more efficient system can be obtained.

### (Wafer Cleaning Water Supply Step)

The wafer cleaning water W1 stored in the reservoir 3 is constantly sent to the cleaning machine 4. When the wafer cleaning water W1 is used, it is ejected from the cleaning nozzle 4A toward a wafer 9, while when the wafer cleaning water W1 is not used, it is returned to the reservoir 3 through the return pipe 7 branched from the wafer cleaning water supply pipe 6. Alternatively, even when the cleaning machine 4 is in operation and the wafer cleaning water W1 is used, only a part of the supplied wafer cleaning water W1 may be used while the rest may be returned to the reservoir 3 through the return pipe 7. In the present embodiment, the return pipe 7 is connected to a predetermined point within 10 m from the tip of the cleaning nozzle 4A, and the wafer cleaning water W1 is returned from the return pipe 7 to the reservoir 3; therefore, even when the cleaning machine 4 is stopped and the wafer cleaning water W1 is not used, it is possible to reduce the amount of the wafer cleaning water W1 retained in the wafer cleaning water supply pipe 6 on the cleaning machine 4 side and minimize the deterioration of the cleaning water quality due to the retention. Furthermore, the pre-dispensing may be unnecessary or minimized, and an effect can therefore be obtained that the above leads to a reduction in the burden on the supply and drainage facilities and an improvement in the excessive use of the chemical solution. If the distance from the tip of the cleaning nozzle 4A to the connection point of the return pipe 7 exceeds 10 m, the above-described effects of reducing the amount of the wafer cleaning water W1 and minimizing the deterioration of the cleaning water quality due to the retention will not be sufficient.

The reason for this may be considered as follows. That is, it is estimated that approximately 4 L of the cleaning water is drained in each pre-dispensing step because the pre-dispensing step generally used at present in the cleaning machine 4 takes 30 to 60 seconds and the usage amount of the wafer cleaning water W1 in one line of the cleaning machine 4 is usually about 4 L/min (the sum of front surface cleaning and back surface cleaning of the wafer 9). The branching point between the wafer cleaning water supply pipe 6 and the return pipe 7 is therefore set within 10 m from the cleaning nozzle 4A of the cleaning machine 4, and the amount of cleaning water discharged during the pre-dispensing can thereby be significantly reduced. In the cleaning machine 4, a PFA tube having a diameter of 4 to 6 mmΦ may be usually as the wafer cleaning water supply pipe 6, but when the branching point between the wafer cleaning water supply pipe and the return pipe is located within 10 m from the nozzle, the maximum amount of the cleaning water remaining in the wafer cleaning water supply pipe is about 1.5 L. Thus, even when the pre-dispensing is carried out, the excess water that is discharged can be reduced to about ⅓, and the time required to supply the cleaning water with stable water quality can be about ¼.

In the present embodiment, as illustrated in FIG. 4, the discharge path 5A may be provided with a removal means such as an ion exchange device for removing the components of the first chemical solution M1 and the second chemical solution M2, and the drain water W2 can thereby be returned to the ultrapure water W supply side. This can significantly reduce the amount of drainage whose raw material is the ultrapure water W.

### Second Embodiment

A second embodiment of the present invention will then be described.

### <Wafer Cleaning Water Supply Device>

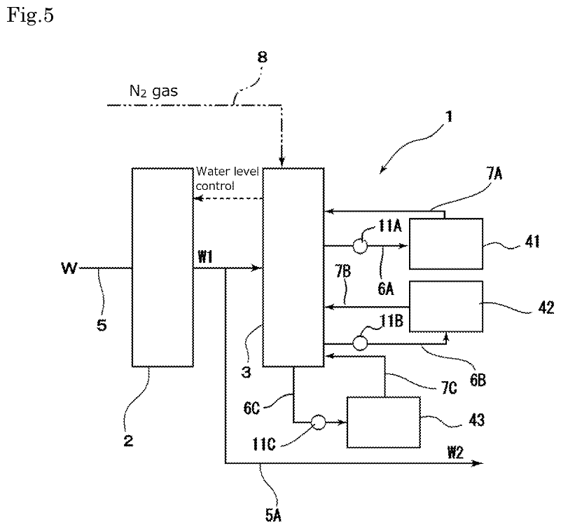

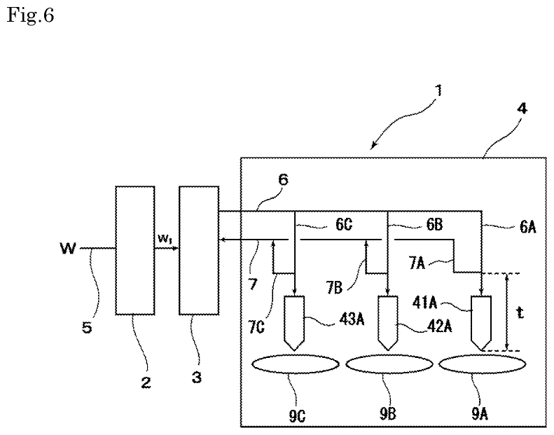

FIGS. 5 and 6 illustrate a wafer cleaning water supply device according to the second embodiment of the present invention. The wafer cleaning water supply device of the second embodiment supplies the cleaning water W1 to a plurality of cleaning machines in the previously described first embodiment. The wafer cleaning water supply device in the second embodiment basically has the same configurations as those in the first embodiment, so the same configurations are denoted with the same reference numerals, and the detailed description will be omitted.

In FIGS. 5 and 6, the wafer cleaning water supply device 1 includes the wafer cleaning water production unit that prepares the wafer cleaning water W1 from the ultrapure water W supplied from the supply path 5, the reservoir 3 for the prepared wafer cleaning water, and wafer cleaning water supply pipes 6 (6A, 6B, and 6C) provided with booster pumps 11A, 11B, and 11C. The wafer cleaning water supply device 1 is configured such that the wafer cleaning water W1 stored in the reservoir 3 can be supplied to two or more (specifically, three) cleaning machines 41, 42, and 43. Return pipes 7 (7A, 7B, and 7C) are connected respectively to the wafer cleaning water supply pipes 6A, 6B, and 6C so as to be branched at a distance (t) from the tips of cleaning nozzles 41A, 42A, and 43A of the cleaning machines 41, 42, and 43, and the wafer cleaning water W1 which is excessive in the cleaning machines 41, 42, and 43 can be returned to the reservoir 3. In the present embodiment, the return pipes 7A, 7B, and 7C may be branched at points within a distance (t) of 10 m from the tips of the cleaning nozzles 41A, 42A, and 43A.

In the wafer cleaning water supply device 1 as described above, the wafer cleaning water production unit 2 and the reservoir 3 for use may be the same as those in the previously described first embodiment.

### <Method of Supplying Wafer Cleaning Water>

The description will be directed to a method of supplying the wafer cleaning water W1 using the wafer cleaning water supply device 1 as described above.

### (Wafer Cleaning Water Preparation Step)

The ultrapure water W is distributed to the supply path 5 from a supply source (not illustrated) of the ultrapure water W, and a predetermined amount of the ultrapure water W is supplied to the wafer cleaning water production unit 2. On the other hand, since the first chemical solution M1 and the second chemical solution M2 are stored in the chemical solution tank 21, the pump 23 is controlled by a control device based on the supply amount of the ultrapure water W (flow volume in the supply path 5) so that the first chemical solution M1 and the second chemical solution M2 have predetermined concentrations, and the first chemical solution M1 and the second chemical solution M2 are supplied from the chemical solution supply pipe 22 to prepare the wafer cleaning water W1. Here, the first chemical solution M1 and the second chemical solution M2 for use may be the same as those in the first embodiment.

### (Storage Step)

The wafer cleaning water W1 thus prepared is supplied to the reservoir 3 without any modification. In this operation, N₂ gas having a constant pressure is supplied to the reservoir 3 from an N₂ gas supply pipe 31 to fill the upper space of the reservoir 3 with the N₂ gas. This can prevent the dissolved oxygen in the wafer cleaning water W1 from increasing in the reservoir 3, thereby suppressing the fluctuations of the pH and the redox potential due to the increase in the dissolved gas.

### (Wafer Cleaning Water Supply Step)

The wafer cleaning water W1 stored in the reservoir 3 can be supplied from the wafer cleaning water supply pipes (6A, 6B and 6C) to the two or more (specifically, three) cleaning machines 41, 42, and 43. At this time, the wafer cleaning water supply pipes 6A, 6B, and 6C are provided with the booster pumps 11A, 11B, and 11C, respectively, and it is therefore possible to ensure the water feeding pressure when supplying the wafer cleaning water W1 to the two or more cleaning machines. The cleaning water W1 is ejected from the cleaning nozzles 41A, 42A, and 43A toward wafers 9A, 9B, and 9C, respectively, while when the wafer cleaning water W1 is not used, it is returned to the reservoir 3 through the return pipes 7 branched from the wafer cleaning water supply pipes 6. Alternatively, even when the cleaning machines 41, 42, and 43 are in operation and the wafer cleaning water W1 is used, only a part of the supplied wafer cleaning water W1 may be used while the rest may be returned to the reservoir 3 through the return pipes (7A, 7B, and 7C). In the present embodiment, the return pipes 7A, 7B, and 7C are connected to predetermined points within 10 m from the tips of the cleaning nozzles 41A, 42A, and 43A, and the wafer cleaning water W1 is returned from the return pipes 7A, 7B, and 7C to the reservoir 3; therefore, even when the cleaning machines 41, 42, and 43 are stopped and the wafer cleaning water W1 is not used, it is possible to reduce the amount of the wafer cleaning water W1 retained in the wafer cleaning water supply pipes 6A, 6B, and 6C on the cleaning machine side and minimize the deterioration of the cleaning water quality due to the retention. Furthermore, the pre-dispensing may be unnecessary or minimized, and an effect can therefore be obtained that the above leads to a reduction in the burden on the supply and drainage facilities and an improvement in the excessive use of the chemical solution.

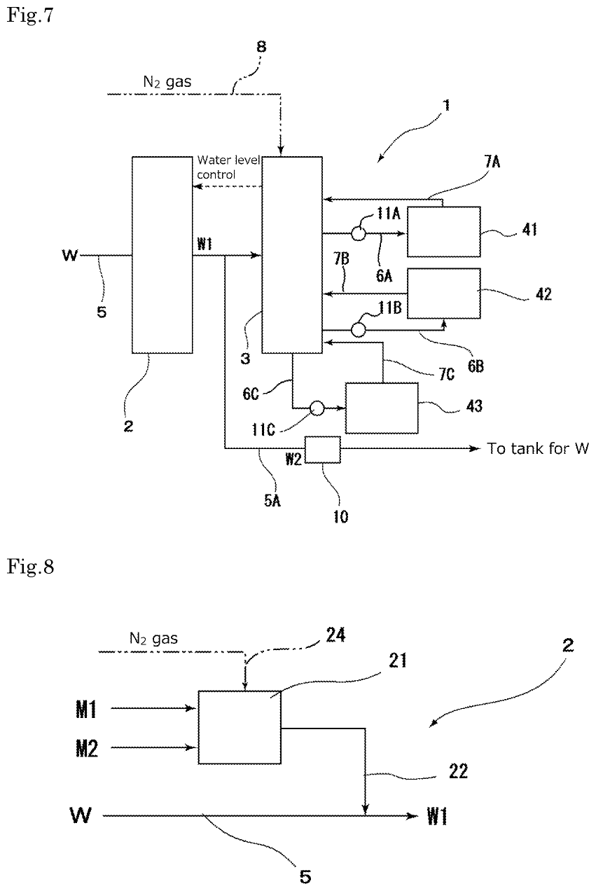

In the present embodiment, as illustrated in FIG. 7, the discharge path 5A may be provided with a removal means such as an ion exchange device for removing the components of the first chemical solution M1 and the second chemical solution M2, and the drain water W2 can thereby be returned to the ultrapure water W supply side. This can significantly reduce the amount of drainage whose raw material is the ultrapure water W.

### <Various Aspects of Wafer Cleaning Water Production Unit 2>

The wafer cleaning water supply device of the present invention has been described above based on the first and second embodiments, but various aspects of the wafer cleaning water production unit 2 can be applied without being limited to the wafer cleaning water production unit 2 of a first aspect used in the above-described embodiments, and such aspects will therefore be exemplified below.

### (Second Aspect of Wafer Cleaning Water Production Unit 2)

The wafer cleaning water production unit 2 of the second aspect basically has the same configurations as those of the wafer cleaning water production unit 2 of the previously described first aspect, so the same configurations are denoted with the same reference numerals, and the detailed description will be omitted.

As illustrated in FIG. 8, the wafer cleaning water production unit 2 includes the chemical solution tank 21 that stores predetermined amounts of the first chemical solution M1 and the second chemical solution M2 having respective predetermined concentrations and the chemical solution supply pipe 22 that communicates from the chemical solution tank 21 to the supply path 5 for the ultrapure water W, and a supply pipe 24 for an N₂ gas as inert gas is connected to and communicates with the chemical solution tank 21 as substitute for the pump 23 that sends and supplies the chemical solutions.

Thus, in the wafer cleaning water production unit 2, the chemical solutions may be sent and supplied by supplying the N₂ gas and push it out into the chemical solution tank 21 without using the pump 23.

### (Third Aspect of Wafer Cleaning Water Production Unit 2)

The wafer cleaning water production unit 2 of the third aspect basically has the same configurations as those of the wafer cleaning water production unit 2 of the previously described first aspect, so the same configurations are denoted with the same reference numerals, and the detailed description will be omitted.

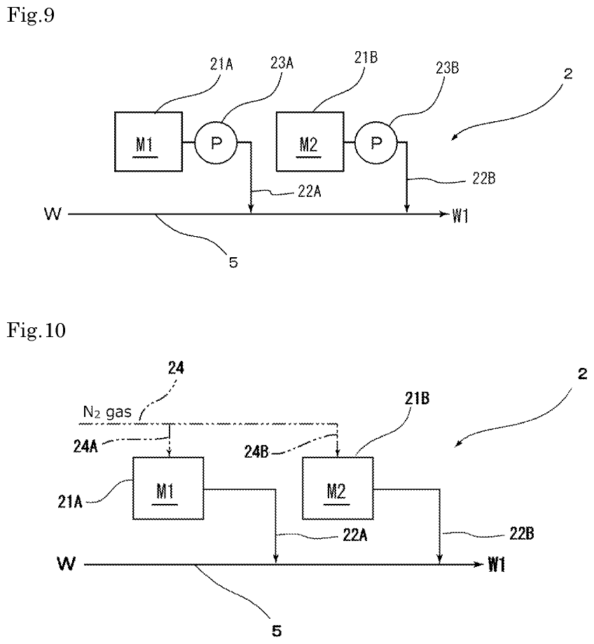

As illustrated in FIG. 9, the wafer cleaning water production unit 2 has a first chemical solution tank 21A that stores a predetermined amount of the first chemical solution M1 having a predetermined concentration, a chemical solution supply pipe 22A that communicates from the first chemical solution tank 21A to the supply path 5 for the ultrapure water W, and a pump 23A that sends and supplies the chemical solution. The wafer cleaning water production unit 2 further has a second chemical solution tank 21B that stores a predetermined amount of the second chemical solution M2 having a predetermined concentration, a chemical solution supply pipe 22B that communicates from the second chemical solution tank 21B to the supply path 5 for the ultrapure water W, and a pump 23B that sends and supplies the chemical solution.

Thus, in the wafer cleaning water production unit 2, the first chemical solution M1 and the second chemical solution M2 may be added separately.

### (Fourth Aspect of Wafer Cleaning Water Production Unit 2)

The wafer cleaning water production unit 2 of the fourth aspect basically has the same configurations as those of the wafer cleaning water production unit 2 of the previously described third aspect, so the same configurations are denoted with the same reference numerals, and the detailed description will be omitted.

As illustrated in FIG. 10, the wafer cleaning water production unit 2 is configured such that, as in the wafer cleaning water production unit 2 of the third embodiment, supply pipes 24A and 24B branched from the supply pipe 24 for an N₂ gas as inert gas are connected to and communicate with the first chemical solution tank 21A and the second chemical solution tank 21B, respectively, as substitute for the pumps 23A and 23B that send and supply the chemical solutions.

Thus, the first chemical solution M1 and the second chemical solution M2 may be sent and supplied by supplying the N₂ gas and push it out into the first chemical solution tank 21A and the second chemical solution tank 21B, respectively, without using the pumps 23A and 23B.

### (Fifth Aspect of Wafer Cleaning Water Production Unit 2)

The wafer cleaning water production unit 2 of the fifth aspect basically has the same configurations as those of the wafer cleaning water production unit 2 of the previously described first aspect, so the same configurations are denoted with the same reference numerals, and the detailed description will be omitted.

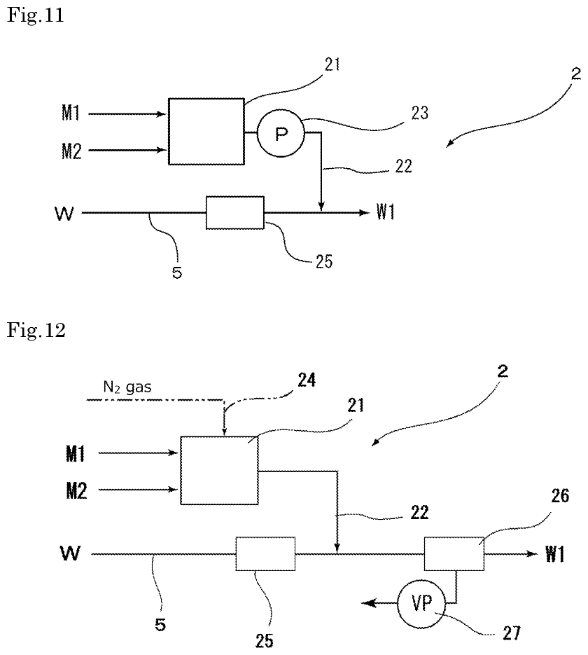

As illustrated in FIG. 11, the wafer cleaning water production unit 2 is composed of the chemical solution tank that stores predetermined amounts of the first chemical solution M1 and the second chemical solution M2 having respective predetermined concentrations, the chemical solution supply pipe 22 that communicates from the chemical solution tank 21 to the supply path 5 for the ultrapure water W, and the pump 23 that supplies the chemical solutions. In addition, the supply path 5 for the ultrapure water W is provided with a hydrogen peroxide removal means 25 before the chemical solution supply pipe 22.

Thus, by providing the hydrogen peroxide removal means before the chemical solution supply pipe 22 of the wafer cleaning water production unit 2, the hydrogen peroxide in the ultrapure water W can be removed to a high degree, and it is therefore possible to more accurately adjust the pH and/or the redox potential with the first chemical solution M1 and the second chemical solution M2.

### (Sixth Aspect of Wafer Cleaning Water Production Unit 2)

The wafer cleaning water production unit 2 of the sixth aspect basically has the same configurations as those of the wafer cleaning water production unit 2 of the previously described fifth aspect, so the same configurations are denoted with the same reference numerals, and the detailed description will be omitted.

As illustrated in FIG. 12, the wafer cleaning water production unit 2 has the same configurations as those in the wafer cleaning water production unit 2 of the fifth embodiment except that a degassing membrane device 26 having a vacuum pump 27 is provided downstream the communicating portion of the chemical solution supply pipe with the supply path 5 for the ultrapure water W.

Thus, by providing the degassing membrane device 26 downstream the communicating portion of the chemical solution supply pipe 22, it is possible to remove the dissolved gas such as oxygen contained in the first chemical solution M1 and the second chemical solution M2. This can suppress the fluctuation in the pH and/or redox potential of the wafer cleaning water W1 after the addition of the first chemical solution M1 and the second chemical solution M2.

### (Seventh Aspect of Wafer Cleaning Water Production Unit 2)

The wafer cleaning water production unit 2 of the seventh aspect basically has the same configurations as those of the wafer cleaning water production unit 2 of the previously described third aspect, so the same configurations are denoted with the same reference numerals, and the detailed description will be omitted.

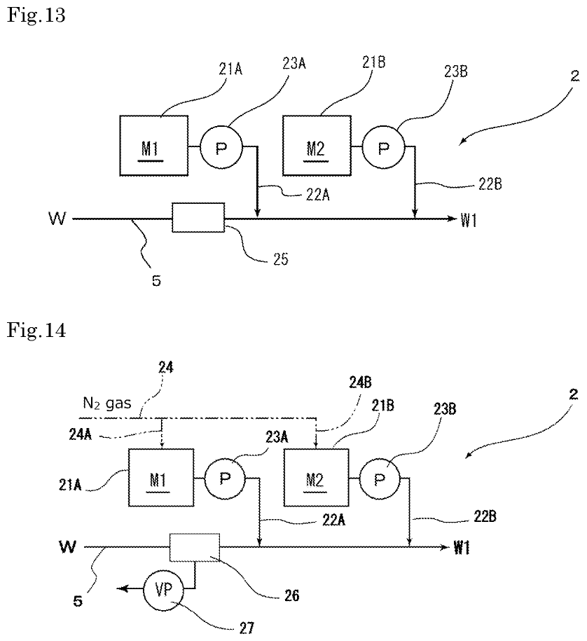

As illustrated in FIG. 13, the wafer cleaning water production unit 2 has a first chemical solution tank 21A that stores a predetermined amount of the first chemical solution M1 having a predetermined concentration, a chemical solution supply pipe 22A that communicates from the first chemical solution tank 21A to the supply path 5 for the ultrapure water W, and a pump 23A that sends and supplies the chemical solution. The wafer cleaning water production unit 2 further has a second chemical solution tank 21B that stores a predetermined amount of the second chemical solution M2 having a predetermined concentration, a chemical solution supply pipe 22B that communicates from the second chemical solution tank 21B to the supply path 5 for the ultrapure water W, and a pump 23B that sends and supplies the chemical solution. In addition, the supply path 5 for the ultrapure water W is provided with the hydrogen peroxide removal means 25 before the chemical solution supply pipe 22A.

Thus, by providing the hydrogen peroxide removal means before the chemical solution supply pipe 22A of the wafer cleaning water production unit 2, the hydrogen peroxide in the ultrapure water W can be removed to a high degree, and it is therefore possible to more accurately adjust the pH and/or the redox potential with the first chemical solution M1 and the second chemical solution M2.

### (Eighth Aspect of Wafer Cleaning Water Production Unit 2)

The wafer cleaning water production unit 2 of the eighth aspect basically has the same configurations as those of the wafer cleaning water production unit 2 of the previously described fourth aspect, so the same configurations are denoted with the same reference numerals, and the detailed description will be omitted.

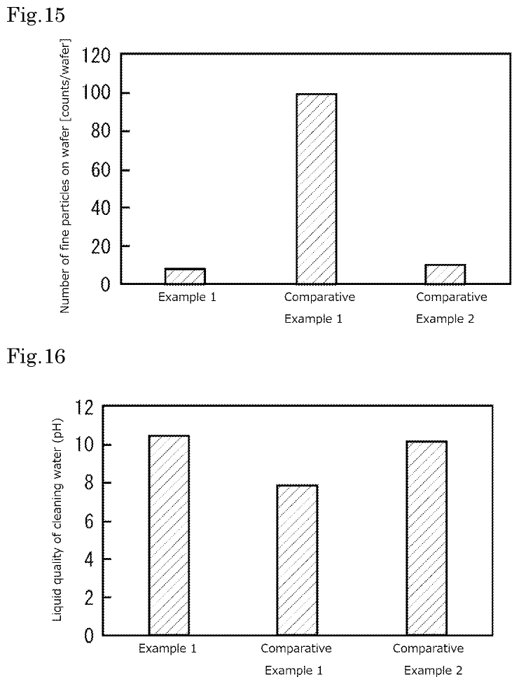

As illustrated in FIG. 14, the wafer cleaning water production unit 2 has a first chemical solution tank 21A that stores a predetermined amount of the first chemical solution M1 having a predetermined concentration, a chemical solution supply pipe 22A that communicates from the first chemical solution tank 21A to the supply path 5 for the ultrapure water W, and a pump 23A that sends and supplies the chemical solution. The wafer cleaning water production unit 2 further has a second chemical solution tank 21B that stores a predetermined amount of the second chemical solution M2 having a predetermined concentration, a chemical solution supply pipe 22B that communicates from the second chemical solution tank 21B to the supply path 5 for the ultrapure water W, and a pump 23B that sends and supplies the chemical solution. The configuration is the same except that the supply path 5 for the ultrapure water W is provided with the degassing membrane device 26, which has the vacuum pump 27, before the chemical solution supply pipe 22A.

Thus, by providing the degassing membrane device 26 before the communicating portion of the chemical solution supply pipe 22A, the dissolved gas such as oxygen contained in the ultrapure water W can be removed to a high degree. It is thus possible to accurately adjust the pH and/or redox potential of the wafer cleaning water W1 after the addition of the first chemical solution M1 and the second chemical solution M2.

While the wafer cleaning water supply device of the present invention has been described above based on the embodiments, the present invention is not limited to the embodiments and various modifications are possible. In the present embodiments, liquids are used as the first chemical solution M1 and the second chemical solution M2 to be added in the wafer cleaning water supply device, but a gas dissolving membrane device may be used, for example, to dissolve gases such as hydrogen (H₂), carbon dioxide (CO₂), and ozone (O₃) thereby to adjust the pH and/or the redox potential.

### EXAMPLES

The present invention will be described in more detail with the following specific examples.

### Example 1

The wafer cleaning water supply device 1 illustrated in FIG. 1 was used to produce ultra-dilute APM (ammonia concentration: 10 ppm (pH of about 10), hydrogen peroxide concentration: 100 ppm (redox potential of 0.05 V)) as the wafer cleaning water W1 through adding predetermined amounts of ammonia as the first chemical solution M1 and hydrogen peroxide as the second chemical solution M2 to the ultrapure water W in the wafer cleaning water production unit 2 and continuing the discharge until the concentrations of ammonia and hydrogen peroxide were stabilized. In the wafer cleaning water supply device 1, the return pipe 7 was connected to the wafer cleaning water supply pipe 6 at a point of 5 m from the tip of the cleaning nozzle 4A, and the wafer cleaning water W1 was constantly circulated by supplying a larger amount of the wafer cleaning water W1 than the ejection amount from the cleaning nozzle 4A of the cleaning machine 4.

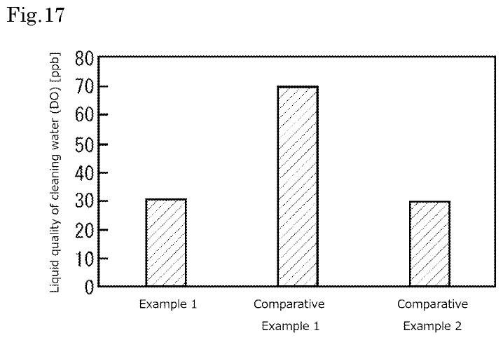

Then, the number of fine particles, pH, and dissolved oxygen concentration of the initial wafer cleaning water W1 ejected from the cleaning nozzle 4A were measured. The results are illustrated in FIGS. 15 to 17.

### Comparative Example 1

In Example 1, after the return pipe 7 of the wafer cleaning water supply device 1 illustrated in FIG. 1 was closed and the wafer cleaning water W was retained for 10 minutes, the number of fine particles, pH, and dissolved oxygen concentration of the initial wafer cleaning water W1 ejected from the cleaning nozzle 4A were measured. The results are illustrated in FIGS. 15 to 17.

### Comparative Example 2

In Example 1, the return pipe 7 was connected to the wafer cleaning water supply pipe 6 at a point of a distance (t) of 15 m from the tip of the cleaning nozzle 4A to enable the circulation.

Then, when the cleaning was stopped, pre-dispensing (ejecting and discarding the wafer cleaning water W1 remaining in a region from the wafer cleaning water supply pipe 6 to the cleaning nozzle 4A) was performed, and the number of fine particles, pH, and dissolved oxygen concentration of the initial wafer cleaning water W1 ejected from the cleaning nozzle 4A at the next cleaning were measured. The results are illustrated in FIGS. 15 to 17.

As apparent from FIGS. 15 to 17, in Example 1 in which the wafer cleaning water W1 was constantly circulated without pre-dispensing, the number of fine particles on the wafer and the pH and dissolved oxygen concentration of the wafer cleaning water W1 were comparable with those in Comparative Example 2 in which the pre-dispensing of the wafer cleaning water W1 remaining in a region from the wafer cleaning water supply pipe 6 to the cleaning nozzle 4A was performed. This is considered to be because the wafer cleaning water W1 was constantly passed through even when the wafer was not cleaned, so that the number of fine particles in the wafer cleaning water W1 and the liquid quality of the cleaning water were able to be kept constant without changing. Moreover, the amount of the discharged wafer cleaning water W1 was reduced by 1 L or more as compared with Comparative Example 2.

On the other hand, in Comparative Example 1 in which the wafer cleaning water W1 was retained in the PFA tube for 10 minutes without pre-dispensing, the number of fine particles on the wafer and the pH and dissolved oxygen concentration of the wafer cleaning water W1 were all significantly worse than those in Comparative Example 2. This is because the PFA tube generally has gas permeability, and impurities such as fine particles are eluted in ultrapure water. It is thus considered that impurities and oxygen and carbon dioxide gas in the atmosphere were dissolved in the wafer cleaning water W1 through the PFA tube to deteriorate the number of fine particles in the cleaning water and its liquid quality. On the other hand, in Comparative Example 2 in which the pre-dispensing was performed, such deterioration was not observed because the wafer cleaning water W1 retained in the PFA tube was discharged. Moreover, in Example 1, the number of fine particles in the cleaning water and the liquid quality of the cleaning water are kept constant without changing because the wafer cleaning water W1 is constantly circulated and passed through even when the wafer is not cleaned, and it is thus considered that the results were comparable with those in Comparative Example 2.

### DESCRIPTION OF REFERENCE NUMERALS

1 Wafer cleaning water supply device
2 Wafer cleaning water production unit
3 Reservoir
4, 41, 42, 43 Cleaning machine
4A, 41A, 42A, 43A Cleaning nozzle
5 Supply path
5A Discharge path for drain water
6, 6A, 6B, 6C Wafer cleaning water supply pipe
7, 7A, 7B, 7C Return pipe
8 Supply pipe for N₂ gas (supply pipe for inert gas)
9, 9A, 9B, 9C Wafer
10 Removal means
11A, 11B, 11C Booster pump
21 Chemical solution tank
21A First chemical solution tank
21B Second chemical solution tank
22, 22A, 22B Chemical solution supply pipe
23, 23A, 23B Pump
24, 24A, 24B Supply pipe for N₂ gas
25 Hydrogen peroxide removal means
26 Degassing membrane device
27 Vacuum pump
W Ultrapure water
W1 Wafer cleaning water
W2 Drain water
M1 First chemical solution
M2 Second chemical solution

1. A wafer cleaning water supply device comprising:
a wafer cleaning water production unit that dissolves a predetermined amount of a chemical agent in a flow volume of ultrapure water thereby to produce wafer cleaning water having a predetermined concentration of the chemical agent;
a reservoir that stores the produced wafer cleaning water;
a wafer cleaning water supply pipe that connects a reservoir and a water cleaning water ejection portion provided in a cleaning machine to supply the wafer cleaning water to the cleaning machine; and
a return pipe that branches from the wafer cleaning water supply pipe and returns part of the wafer cleaning water which is excessive in the cleaning machine to the reservoir,
wherein the return pipe branches at a point of 10 m or less from the wafer cleaning water ejection portion of the cleaning machine.

2. The wafer cleaning water supply device according to claim 1, wherein the return pipe branches in the cleaning machine, and the wafer cleaning water can be circulated through the reservoir, the wafer cleaning water supply pipe, and the return pipe.

3. The wafer cleaning water supply device according to claim 1, wherein:
the wafer cleaning water production unit comprises a chemical agent tank which stores the chemical agent that is a liquid, and
the wafer cleaning water production unit has at least one configuration of (1) or (2):
(1) the water cleaning water production unit further comprises a liquid supply pump to transport and add the chemical agent to the ultrapure water;
(2) the chemical agent tank is a closed tank and the water cleaning water production unit further comprises a pressure-feeding unit that supplies inert gas to the closed tank such that the chemical agent is pushed out from the chemical agent tank and added to the ultrapure water.

4. The wafer cleaning water supply device according to claim 1, wherein the reservoir comprises a water level detector which detects a water level of the wafer cleaning water in the reservoir, and the wafer cleaning water supply device further comprises a controller to control start/stop of production of the wafer cleaning water in the wafer cleaning water production unit based on liquid level information obtained by the water level detector.

5. The wafer cleaning water supply device according to claim 1, wherein the reservoir comprises a water level detector which detects a water level of the wafer cleaning water in the reservoir, and the wafer cleaning water supply device further comprises a controller to control a production amount of the wafer cleaning water in the wafer cleaning water production unit to a production level among a predetermined multiple production levels, based on liquid level information obtained by the water level detector.

6. The wafer cleaning water supply device according to claim 1, further comprising a discharge port provided between the wafer cleaning water production unit and the reservoir.

7. The wafer cleaning water supply device according to claim 6, wherein the discharge port is connected to a discharge path that communicates with a supply source for the ultrapure water, and the discharge path is provided with an ion exchange device and/or a catalyst device capable of removing a chemical agent component in the wafer cleaning water.

8. The wafer cleaning water supply device according to claim 1, wherein the production unit comprises a dis solved-oxygen-removal unit which removes dissolved oxygen from the ultrapure water or the wafer cleaning water.
